(19) United States
(12) Patent Application Publication
(10) Pub. No.: US 2008/0204687 A1
(43) Pub. Date: Aug. 28, 2008

(54) Exposing method, exposure apparatus, device fabricating method, and substrate for immersion exposure

(75) Inventor: Katsushi Nakano, Kawagaya-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 12/071,468

(22) Filed: Feb. 21, 2008

Related U.S. Application Data
(60) Provisional application No. 60/903,290, filed on Feb. 26, 2007.

(30) Foreign Application Priority Data
Feb. 23, 2007 (JP) 2007-043980

(51) Int. Cl. G03B 27/42; G03F 7/20; G03F 7/004

(52) U.S. Cl. 355/53; 430/322; 430/270.1

(57) ABSTRACT

An exposing method which exposes a substrate through a liquid, the pH value of the liquid is adjusted in accordance with a material of a surface layer of the substrate that contacts the liquid.

### CROSS-REFERENCE TO RELATED APPLICATION

This application is a non-provisional application claiming benefit of provisional application No. 60/903,290 filed Feb. 26, 2007, and claims priority to Japanese Patent Application No. 2007-043980, filed Feb. 23, 2007, the contents of which are incorporated herein by reference.

### BACKGROUND

1. Field of the Invention

The present invention relates to an exposing method that exposes a substrate through a liquid, as well as to an exposure apparatus, a device fabricating method, and a substrate for immersion exposure.

2. Description of Related Art

In a photolithographic process, an immersion exposure technique has been proposed that exposes a substrate through a liquid, as disclosed in PCT International Publication No. WO99/49504.

If a substrate is irradiated with exposure light in a state wherein foreign matter adheres to its front surface, then there is a possibility that exposure failures, e.g., defects in the pattern formed on the substrate, will occur. Consequently, there is a need to prevent foreign matter from adhering to the front surface of the substrate.

A purpose of some aspects of the invention is to provide: an exposing method that can prevent exposure failures caused by foreign matter adhering to the front surface of the substrate and thereby expose the substrate satisfactorily; an exposure apparatus; a device fabricating method; and a substrate for immersion exposure.

### SUMMARY

A first aspect of the invention provides an exposing method that comprises exposing a substrate through a liquid, and adjusting a pH value of the liquid in accordance with a material of a surface layer of the substrate that contacts the liquid.

According to the first aspect of the invention, it is possible to prevent exposure failures.

A second aspect of the invention provides an exposing method that exposes a substrate through a liquid, wherein the substrate includes a first portion that comprises a first material and a second portion that comprises a second material that is different from the first material; and a zeta potential of the first material and a zeta potential of the second material with respect to the liquid are of the same polarity.

According to the second aspect of the invention, it is possible to prevent exposure failures.

A third aspect of the invention provides a device fabricating method that comprises: exposing a substrate using an exposing method according to the abovementioned aspects; and developing the exposed substrate.

According to the third aspect of the invention, it is possible to fabricate a device using an exposing method that can prevent exposure failures.

A fourth aspect of the invention provides an exposure apparatus that exposes a substrate through a liquid, and comprises: an adjustment apparatus that adjusts a pH value of the liquid in accordance with a material of a surface layer of the substrate that contacts the liquid.

According to the fourth aspect of the invention, it is possible to prevent exposure failures.

A fifth aspect of the invention provides a device fabricating method that comprises: exposing the substrate using the exposure apparatus according to the abovementioned aspects; and developing the exposed substrate.

According to the fifth aspect of the invention, it is possible to fabricate a device using an exposure apparatus that can prevent exposure failures.

A sixth aspect of the invention provides a substrate for immersion exposure that is irradiated with exposure light through a liquid, and comprises: a first portion that comprises a first material; and a second portion that comprises a second material that is different from the first material; wherein, a zeta potential of the first material and a zeta potential of the second material with respect to the liquid are of the same polarity.

According to the sixth aspect of the invention, it is possible to prevent exposure failures.

According to the some aspects of the present invention, it is possible to prevent exposure failures and thereby expose a substrate satisfactorily. Accordingly, a device that has the desired performance can be manufactured.

### BRIEF DESCRIPTION OF THE DRAWINGS

FIG. 1 is a schematic block diagram that shows a device fabrication system that comprises an exposure apparatus according to a first embodiment.

FIG. 2 is a schematic block diagram that shows an exposure apparatus according to the first embodiment.

FIG. 3A schematically shows one example of a substrate according to the first embodiment.

FIG. 3B schematically shows one example of a substrate according to the first embodiment.

FIG. 4 is a flow chart diagram that shows one example of a device fabricating method according to the first embodiment.

FIG. 5A is a schematic drawing for explaining one example of a device fabricating method according to the first embodiment.

FIG. 5B is a schematic drawing for explaining one example of a device fabricating method according to the first embodiment.

FIG. 5C is a schematic drawing for explaining one example of a device fabricating method according to the first embodiment.

FIG. 5D is a schematic drawing for explaining one example of a device fabricating method according to the first embodiment.

FIG. 6 is a schematic drawing that shows one example of the operation of the exposure apparatus.

FIG. 7 is a schematic drawing for explaining the relationship between a surface layer of the substrate and foreign matter in a liquid.

FIG. 8 schematically shows another example of a substrate according to the first embodiment.

FIG. 9 is a schematic block diagram that shows the exposure apparatus according to a second embodiment.

FIG. 10 is a schematic drawing that shows the relationship between the pH value of the liquid and the zeta potentials of substances with respect to that liquid.

FIG. 11A schematically shows another example of the substrate.

FIG. 11B schematically shows another example of the substrate.

FIG. 12 is a flow chart diagram that shows one example of a process of fabricating a microdevice.

### DESCRIPTION OF EMBODIMENTS

The following explains the embodiments of the present invention referencing the drawings, but the present invention is not limited thereto. Furthermore, the following explanation defines an XYZ orthogonal coordinate system and the positional relationships among members are explained referencing this system. Furthermore, prescribed directions within the horizontal plane are the X axial directions, directions that are orthogonal to the X axial directions in the horizontal plane are the Y axial directions, and directions that are orthogonal to the X axial directions and the Y axial directions (i.e., the vertical directions) are the Z axial directions. In addition, the rotational (the inclined) directions around the X, Y, and Z axes are the θX, θY, and θZ directions, respectively.

### First Embodiment

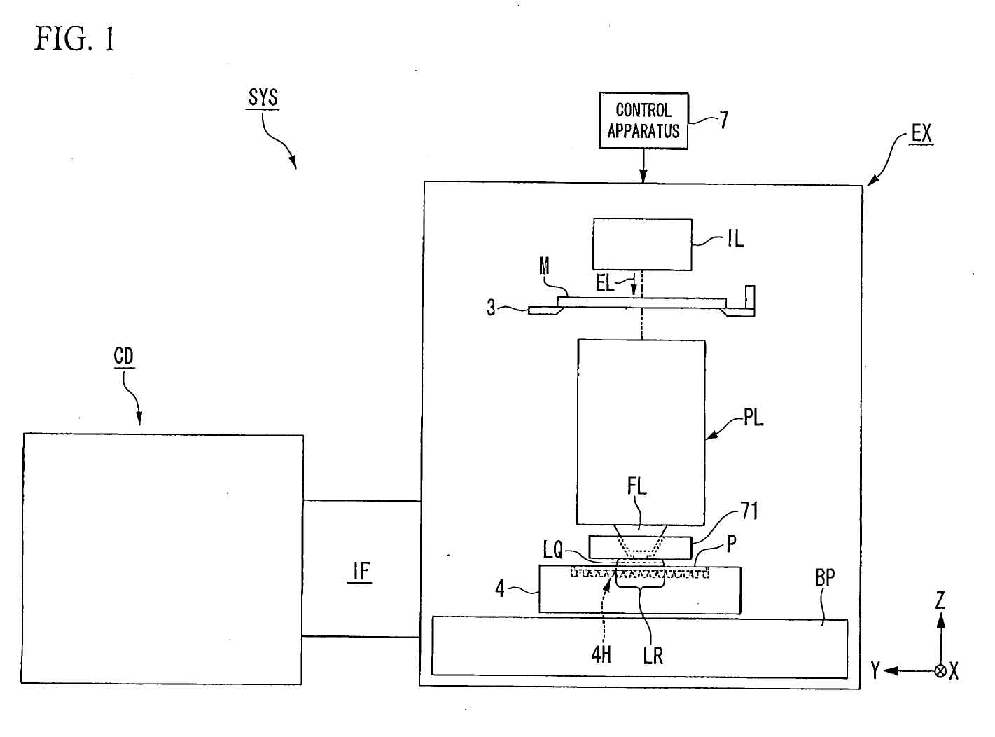

A first embodiment will now be explained. FIG. 1 shows a device fabricating system SYS that comprises an exposure apparatus EX according to the first embodiment. In FIG. 1, the device fabrication system SYS comprises the exposure apparatus EX and a coater and developer apparatus CD, which is connected to the exposure apparatus EX.

The exposure apparatus EX comprises a mask stage 3, which is capable of moving while holding a mask M; a substrate stage 4, which is capable of moving while holding a substrate P; an illumination system IL, which illuminates the mask M that is supported by the mask stage 3 with exposure light EL; a projection optical system PL, which projects an image of a pattern of the mask M that is illuminated by the exposure light EL to the substrate P; and a control apparatus 7, which controls the entire operation of the exposure apparatus EX.

Furthermore, the mask M spoken of herein includes a reticle wherein a device pattern is formed that is projected onto the substrate P. In addition, a transmitting type mask is used as the mask M in the present embodiment, but a reflection type mask may also be used. The transmission-type mask is not limited to a binary mask on which a pattern is formed with a shading film, and also includes, for example, a phase-shift mask such as a half-tone type or a spatial frequency modulation type.

The exposure apparatus EX of the present embodiment is an immersion exposure apparatus that exposes the substrate P by irradiating the substrate P with the exposure light EL through a liquid LQ, and comprises a nozzle member 71 for filling an optical path space K of the exposure light EL with the liquid LQ. In the present embodiment, water (pure water) is used as the liquid LQ.

The nozzle member 71 of the present embodiment is disposed in the vicinity of a last optical element FL, which is the optical element of the plurality of optical elements of the projection optical system PL that is closest to the image plane of the projection optical system PL. An immersion space LR is formed by holding the liquid LQ at least a part of a space between the nozzle member 71 and an object so that the optical path space K of the exposure light EL between a lower surface (emergent surface) of the last optical element FL and a front surface of the object is filled with the liquid LQ. Objects that are capable of opposing the nozzle member 71 and the lower surface of the last optical element FL include the substrate P and the substrate stage 4. The immersion space LR is formed between the nozzle member 71 and the lower surface of the last optical element FL on one side and the front surface of the substrate P on the other side at least during the exposure of the substrate P. While the front surface of the substrate P is irradiated with the exposure light EL, the liquid LQ in the immersion space LR contacts such.

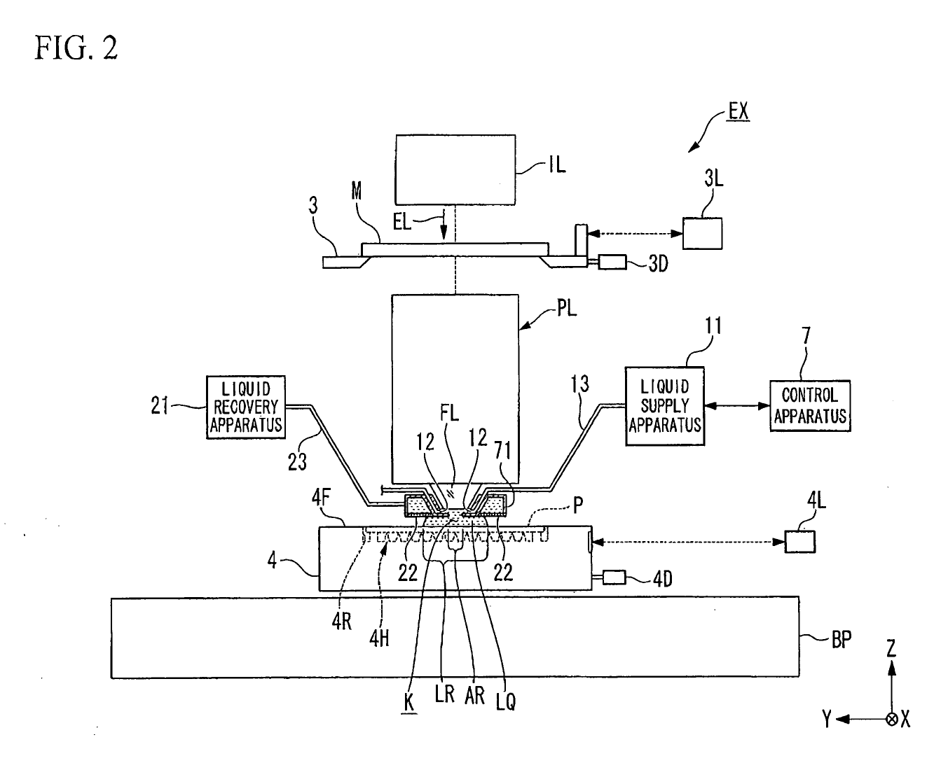

In the present embodiment, the immersion space LR is formed so that part of the area (a local area) of the front surface of the substrate P is covered with the liquid LQ during the exposure of the substrate P. Namely, the exposure apparatus EX of the present embodiment adopts a local liquid immersion system wherein the immersion space LR is formed so that part of the area of the front surface of the substrate P that includes a projection area (i.e., the projection area AR in FIG. 2) of the projection optical system PL is covered with the liquid LQ during the exposure of the substrate P.

The exposure apparatus EX of the present embodiment is a scanning type exposure apparatus (a so-called scanning stepper) that projects the image of the pattern formed on the mask M onto the substrate P while synchronously moving the mask M and the substrate P in prescribed scanning directions. In the present embodiment, the scanning directions (the synchronous movement directions) of the substrate P and of the mask M are the Y axial directions. The exposure apparatus EX moves the substrate P in the Y axial directions with respect to the projection area of the projection optical system PL, and radiates the exposure light EL onto the substrate P through the projection optical system PL and the liquid LQ while moving the mask M in the Y axial directions with respect to the illumination area of the illumination system IL synchronized to the movement of the substrate P in the Y axial directions. Thereby, the image of the pattern of the mask M is projected onto the substrate P, which is thereby exposed with the exposure light EL.

The coater and developer apparatus CD includes a coating apparatus (not shown) that coats the base material of the substrate P with, for example, a photosensitive material (photoresist) prior to the exposure, and a developer apparatus (not shown), which develops the substrate P after the exposure. The exposure apparatus EX and the coater and developer apparatus CD are connected via an interface IF, and substrate P can be transported by a transport apparatus (not shown) therebetween via the interface IF. In addition, in the present embodiment, the coater and developer apparatus CD comprises a processing apparatus that is capable of forming an HMDS (hexamethyldisilazane) layer on the base material. The processing apparatus supplies gaseous HMDS to the ambient space surrounding the base material in a state wherein the base material is heated. Thereby, the front surface of the base material and the gaseous HMDS contact one another and form the HMDS layer on the base material. In the explanation below, the layer of HMDS is properly called an HMDS layer, and the process that forms the HMDS layer on the base material is properly called the HMDS process.

FIG. 2 is a schematic block diagram that shows one example of the exposure apparatus EX. In FIG. 2, the illumination system IL illuminates a prescribed illumination area on the mask M with the exposure light EL, which has a uniform luminous flux intensity distribution. In the present embodiment, ArF excimer laser light is used as the exposure light EL that is emitted from the illumination system IL.

The mask stage 3, in a state wherein it holds the mask M, is movable in the X axial, Y axial, and θZ directions by the drive of a mask stage drive apparatus 3D that comprises an actuator, e.g., a linear motor. A laser interferometer 3L measures positional information of the mask stage 3 (the mask M) in the X axial, Y axial, and θZ directions. Based on the measurement result of the laser interferometer 3L, the control apparatus 7 controls the position of the mask M, which is held by the mask stage 3, by driving the mask stage drive apparatus 3D.

The projection optical system PL projects an image of the pattern of the mask M to the substrate P at a prescribed projection magnification. The projection optical system PL of the present embodiment is a reduction system that has a projection magnification of, for example, ¼, ⅕, or ⅛. Furthermore, the projection optical system PL may also be a reduction system, a unity magnification system, or an enlargement system. In addition, the projection optical system PL may be: a dioptric system that does not include catoptric elements; a catoptric system that does not include dioptric elements; or a catadioptric system that includes both catoptric elements and dioptric elements. In addition, the projection optical system PL may form either an inverted image or an erect image.

The substrate stage 4 comprises a substrate holder 4H that holds the substrate P and, in a state wherein the substrate P is held by the substrate holder 4H, is movable on a base member BP in six degrees of freedom, i.e., the X axial, Y axial, Z axial, θX, θY, and θZ directions, by a substrate stage drive apparatus 4D that includes an actuator, e.g., a linear motor. The substrate holder 4H is disposed in a recessed part 4R of the substrate stage 4. The substrate holder 4H holds the substrate P so that the front surface thereof and the XY plane are substantially parallel. In the present embodiment, an upper surface 4F around the recessed part 4R of the substrate stage 4 and the front surface of the substrate P held by the substrate holder 4H are disposed substantially within the same plane (they are flush with one another).

A laser interferometer 4L measures positional information of the substrate stage 4 (the substrate P) in the X axial, the Y axial, and the θZ directions, and a focus and level detection system (not shown) detects surface position information (positional information related to the Z axial, the θX, and the θY directions) of the front surface of the substrate P held by the substrate holder 4H of the substrate stage 4. Based on the measurement result of the laser interferometer 4L and the detection results of the focus and level detection system, the control apparatus 7 controls the position of the substrate P, which is held by the substrate stage 4, by driving the substrate stage drive apparatus 4D.

The exposure apparatus EX comprises a supply port 12, which supplies the liquid LQ to the optical path space K of the exposure light EL, and a recovery port 22, which recovers the liquid LQ. In the present embodiment, the supply port 12 and the recovery port 22 are disposed in the nozzle member 71. A liquid supply apparatus 11 is connected to the supply port 12 via a supply pipe 13. A liquid recovery apparatus 21 is connected to the recovery port 22 via a recovery pipe 23. In the present embodiment, a porous member (mesh) is disposed in the recovery port 22.

The liquid supply apparatus 11 is capable of supplying the liquid LQ, which is pure and the temperature of which has been adjusted. The liquid recovery apparatus 21 comprises a vacuum system and is capable of recovering the liquid LQ. The liquid LQ that is fed from the liquid supply apparatus 11 is supplied to the optical path space K through the supply pipe 13 and the supply port 12. By driving the liquid recovery apparatus 21, which includes the vacuum system, the liquid LQ that is suctioned via the recovery port 22 is recovered by the liquid recovery apparatus 21 through the recovery pipe 23. The control apparatus 7 forms the immersion space LR so that the liquid LQ fills the optical path space K of the exposure light EL by performing the liquid supply operation using the liquid supply apparatus 11 and the liquid recovery operation using the liquid recovery apparatus 21 in parallel.

At least during the projection of the image of the pattern of the mask M onto the substrate P the exposure apparatus EX uses the nozzle member 71 to form the immersion space LR so that the liquid LQ fills the optical path space K of the exposure light EL. The exposure apparatus EX irradiates the substrate P, which is held by the substrate holder 4H, with the exposure light EL, which passed through the mask M, through the projection optical system PL and the liquid LQ of the immersion space LR. Thereby, the image of the pattern of the mask M is projected onto the substrate P, which is thereby exposed.

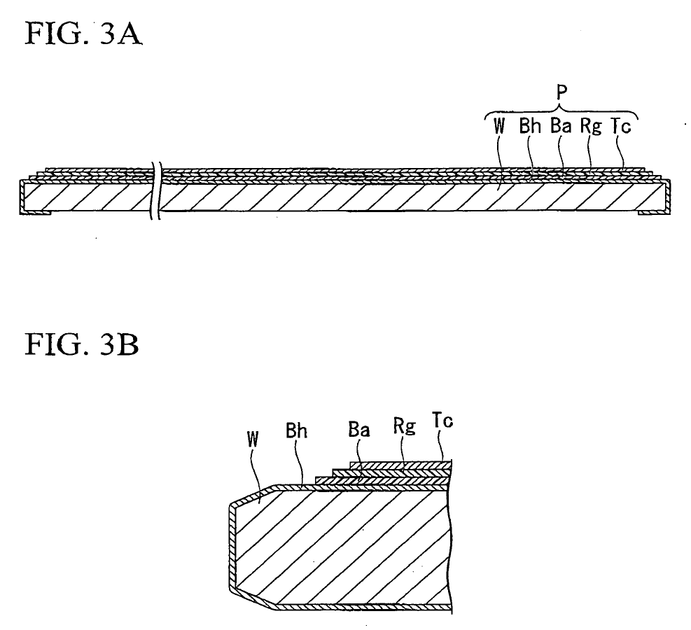

FIGS. 3A and 3B shows one example of the substrate P, wherein FIG. 3A is a side cross sectional view and FIG. 3B is an enlarged view of the vicinity of the circumferential edge of the substrate P in FIG. 3A. In FIGS. 3A and 3B, the substrate P comprises a base material W, an HMDS layer Bh that is formed on the base material W, an antireflection layer (bottom ARC; antireflective coating) Ba that is formed on the HMDS layer Bh, a photosensitive layer Rg that is formed on the antireflection layer Ba, and a protective layer Tc that is formed on the photosensitive layer Rg.

The base material W includes a semiconductor wafer or a silicon substrate. The HMDS layer Bh is formed so that it covers an upper surface of the base material W, a side surface of the base material W, and part of a lower surface of the base material W. The antireflection layer Ba is formed so that it covers the majority of the upper surface area of the HMDS layer Bh—excluding a circumferential edge area of the HMDS layer Bh. The photosensitive layer Rg is formed so that it covers the majority of the upper surface area of the antireflection layer Ba—excluding a circumferential edge area of the antireflection layer Ba. Namely, in the present embodiment, the outer diameter of the photosensitive layer Rg is slightly smaller than the outer diameter of the antireflection layer Ba when viewed from the upper surface side. The protective layer Tc is formed so that it covers the majority of the upper surface area of the photosensitive layer Rg—excluding a circumferential edge area of the photosensitive layer Rg. The HMDS layer Bh is formed so that the front surface of the base material W does not contact the photosensitive layer Rg and the protective layer Tc on the outer side of the antireflection layer Ba.

In the present embodiment, the surface layer of the substrate P is formed by the protective layer Tc. When an immersion exposure is performed on the substrate P, the protective layer Tc of the substrate P and the liquid LQ of the immersion space LR contact one another. In addition, at least part of the photosensitive layer Rg, the antireflection layer Ba, and the HMDS layer Bh is formed below the protective layer Tc (between the protective layer Tc and the base material W).

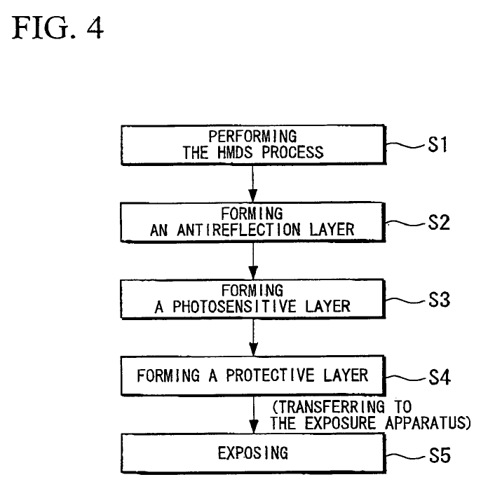

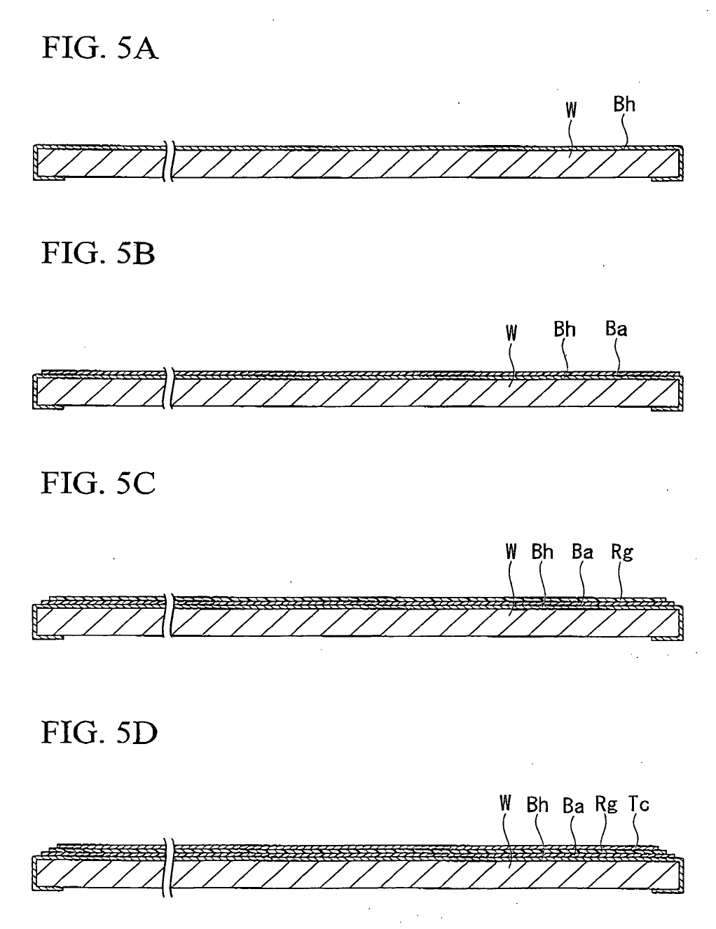

The following explains the procedure for fabricating the substrate P discussed above, referencing the flow chart diagram in FIG. 4 and the schematic drawing in FIGS. 5A, 5B, 5C and 5D. Furthermore, in the explanation below, the constitution wherein at least one of the HMDS layer Bh, the antireflection layer Ba, the photosensitive layer Rg, and the protective layer Tc is formed on the surfaces (including the upper surface, the side surface, and the lower surface) of the base material W is properly called the substrate P.

The HMDS process, which forms the HMDS layer Bh on the upper surface, the side surface, and part of the lower surface of the base material W, is performed by the processing apparatus of the coater and developer apparatus CD (step S1). As shown in FIG. 5A, the HMDS layer Bh is formed so that it covers the upper surface of the base material W, the side surface of the base material W, and the circumferential edge area of the lower surface of the base material W.

After the HMDS layer Bh is formed on the base material W, the antireflection layer Ba is formed on the HMDS layer Bh as shown in FIG. 5B (step S2). The process that forms the antireflection layer Ba includes: a process that forms a film of an antireflection material, from which the antireflection layer Ba is formed, on the substrate P (on the HMDS layer Bh); and an edge rinsing process that eliminates the antireflection material film from the circumferential edge part of the substrate P, including the circumferential edge area of its upper surface, its side surface, and the circumferential edge area of its rear surface.

The antireflection material film can be formed on the substrate P (on the HMDS layer Bh) using, for example, a spin coating method (coating method), or a vacuum evaporation method (depositing method) such as CVD (chemical vapor deposition) or PVD (physical vapor deposition). In the present embodiment, the antireflection material film is formed on the substrate P (on the HMDS layer Bh) using the spin coating method in the coater and developer apparatus CD. The substrate P is coated with the antireflection material using the spin coating method, after which the edge rinsing process is performed to eliminate the antireflection material at the circumferential edge part of the substrate P using a solvent, e.g., a thinner. Thereby, the antireflection layer Ba is formed on the majority upper surface area of the HMDS layer Bh—excluding the circumferential edge area. After the edge rinse, the HMDS layer Bh is not eliminated and remains on the circumferential edge part of the substrate P. Namely, the HMDS layer Bh is formed on the upper surface of the base material W on the outer side of the antireflection layer Ba, as well as on the side surface and part of the lower surface of the base material W.

After the antireflection layer Ba is formed on the substrate P, the photosensitive layer Rg is formed on the antireflection layer Ba, as shown in FIG. 5C (step S3). The process that forms the photosensitive layer Rg includes a process wherein a film of the photosensitive material (photoresist), which is for forming the photosensitive layer Rg, is formed on the substrate P, and an edge rinsing process wherein the film of the photosensitive material is eliminated from the circumferential edge part of the substrate P. In the present embodiment, a chemically amplified resist is used as the photosensitive material. In the present embodiment, the film of the photosensitive material is formed on the substrate P (on the antireflection layer Ba) in the coater and developer apparatus CD using the spin coating method. After the spin coating method is used to coat the substrate P with the photosensitive material, the edge rinsing process is performed wherein a solvent or the like is used to eliminate the photosensitive material from the circumferential edge part of the substrate P. Thereby, the photosensitive layer Rg is formed in the majority of the upper surface area of the antireflection layer Ba—excluding the circumferential edge area. After the edge rinse, the HMDS layer Bh is not eliminated and remains on the circumferential edge part of the substrate P.

As shown in FIG. 5D, after the photosensitive layer Rg is formed on the substrate P, the protective layer Tc is formed on the photosensitive layer Rg (step S4). The process that forms the protective layer Tc includes a process wherein a protective material film, which is for forming the protective layer Tc, is formed on the substrate P, and an edge rinsing process wherein the protective material film is eliminated from the circumferential edge part of the substrate P. The protective layer Tc is a material layer that is called a topcoat layer and functions to protect at least one of the photosensitive layer Rg, the antireflection layer Ba, and the base material W from, for example, the liquid LQ. In addition, the protective layer (topcoat layer) Tc is liquid repellent (water repellent) with respect to the liquid LQ. The contact angle of the liquid LQ on the surface of the protective layer Tc is 90 degrees or more. A material that includes, for example, fluorine can be used as the protective material with which the protective layer Tc is formed. In the present embodiment, the spin coating method is used to form the protective material film on the substrate P (on the photosensitive layer Rg) in the coater and developer apparatus CD. After the spin coating method is used to coat the substrate P with the protective material, the edge rinsing process is performed to eliminate the protective material from the circumferential edge part of the substrate P using, for example, a solvent. Thereby, the protective layer Tc is formed on the upper surface of the substrate P. After the edge rinse, the HMDS layer Bh is not eliminated and remains on the circumferential edge part of the substrate P.

In the present embodiment, the protective layer Tc is formed so that circumferential portions of the antireflection layer Ba and the photosensitive layer Rg, which are formed between the protective layer Tc and the HMDS layer Bh, are exposed.

In addition, prescribed processes, such as a baking process, are performed as needed and with prescribed timings for each of the operations that form the HMDS layer Bh, the antireflection layer Ba, the photosensitive layer Rg, and the protective layer Tc.

After the processes in the coater and developer apparatus CD are complete, a prescribed transport apparatus transports the substrate P to the exposure apparatus EX.

The exposure apparatus EX forms the immersion space LR between the nozzle member 71 and the last optical element FL on one side and the substrate P on the other side, and irradiates the substrate P with the exposure light EL through the liquid LQ of the immersion space LR (step S5).

In the present embodiment, the front surface (the surface layer) of the substrate P is formed by the protective layer Tc. The liquid LQ of the immersion space LR contacts the protective layer Tc of the substrate P. Because the liquid contact surface that contacts the liquid LQ of the substrate P is formed by the protective layer Tc, which is liquid repellent, the immersion space LR can be formed on the substrate P satisfactorily. In addition, the liquid repellent protective layer Tc can increase the recoverability of the liquid LQ, which makes it possible to prevent the liquid LQ from remaining on the substrate P.

The substrate P is transported to the coater and developer apparatus CD after it is exposed, undergoes a prescribed process, such as a post-baking process, after which a development process is performed thereupon using the developer apparatus. Furthermore, a prescribed post-process, such as a dry etching process, is performed to form the pattern on the substrate P.

In the present embodiment, the zeta potential of the protective material with which the protective layer Tc is formed, the zeta potential of the photosensitive material with which the photosensitive layer Rg is formed, and the zeta potential of the antireflection material with which the antireflection layer Ba is formed are all of the same polarity. Namely, in the present embodiment, the protective material, the photosensitive material, and the antireflection material that are used are all selected so that the zeta potentials of the protective layer Tc, the photosensitive layer Rg, and the antireflection layer Ba are all of the same polarity. In the present embodiment, the polarities of the zeta potentials of the protective layer Tc (the protective material), the photosensitive layer Rg (the photosensitive material), and the antireflection layer Ba (the antireflection material) are all negative.

Generally, the zeta potential of a prescribed material varies in accordance with the pH value of the liquid that contacts that material. In the present embodiment, the liquid that contacts the substrate P is water (pure water), which has a pH value of substantially seven. In the explanation below, the zeta potential of the prescribed material with respect to the liquid LQ (water), which has a pH value of substantially seven, is simply called the zeta potential.

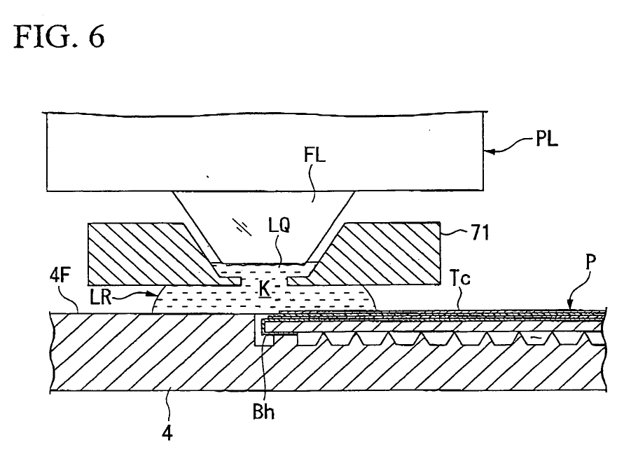

FIG. 6 shows a state wherein the immersion space LR is formed in the circumferential edge of the upper surface area of the substrate P. When, for example, the circumferential edge of the upper surface area of the substrate P is exposed or when the immersion space LR is moved to the upper surface 4F of the substrate stage 4, there is a possibility that the immersion space LR will be disposed in a gap between the upper surface of the substrate P held by the substrate holder 4H and the upper surface 4F of the substrate stage 4 provided around the substrate P, as shown in FIG. 6. In the present embodiment, the upper surface 4F of the substrate stage 4 is liquid repellent and the upper surface and the side surface of the substrate P are formed by the liquid repellent protective layer Tc and the HMDS layer Bh, which prevents the liquid LQ from penetrating the gap between the upper surface of the substrate P and the upper surface 4F of the substrate stage 4.

As shown in FIG. 6, if the circumferential edge part of the substrate P contacts the liquid LQ of the immersion space LR, then there is a possibility that part of the antireflection material film, the photosensitive material film, and the protective material film on the circumferential edge part of the substrate P will peel off. Part of the film that peels off may become foreign matter. For example, there is a possibility that the part of the film that peels off will mix with the liquid LQ as foreign matter and adhere to the front surface of the substrate P. If the substrate P is irradiated with the exposure light EL in a state wherein foreign matter adheres to its front surface, then there is a possibility that exposure failures will occur, e.g., defects will occur in the pattern formed on the substrate P.

Nevertheless, in the present embodiment, even if, for example, part of the photosensitive layer Rg (photosensitive material) below the protective layer Tc peels off of the substrate P and mixes with the liquid LQ as foreign matter, it is possible to prevent that part from adhering to the front surface of the substrate P (the front surface of the protective layer Tc) because the zeta potential of the protective layer Tc (the protective material) that forms the front surface (the surface layer) of the substrate P and the zeta potential of the photosensitive layer Rg (the photosensitive material) are of the same polarity.

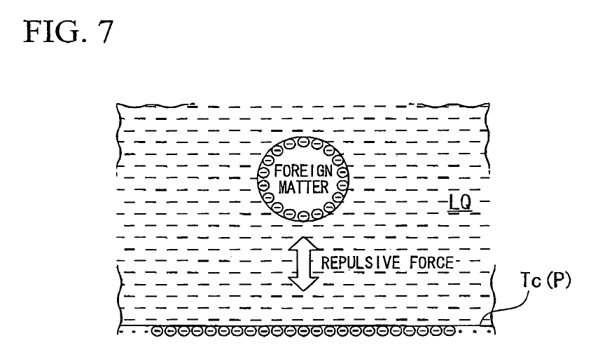

FIG. 7 is a schematic drawing for explaining the relationship between the front surface of the substrate P (the front surface of the protective layer Tc) that contacts the liquid LQ of the immersion space LR and the foreign matter (part of the photosensitive layer Rg) in the liquid LQ. In FIG. 7, the zeta potential of the protective layer Tc is negative and the zeta potential of the foreign matter is also negative. Thus, the zeta potential of the protective layer Tc and the zeta potential of the foreign matter are of the same polarity, thereby generating a repulsive force, which is caused by Coulomb force, between the protective layer Tc and the foreign matter in the liquid LQ. Accordingly, it is possible to prevent the foreign matter from adhering to the front surface of the protective layer Tc. In addition, even if the foreign matter adheres to the front surface of the protective layer Tc, the zeta potential of the protective layer Tc and the zeta potential of the foreign matter are of the same polarity, which makes it possible to separate the foreign matter from the front surface of the protective layer Tc with a slight force, e.g., the force by the flow of the liquid LQ onto the foreign matter. In addition, the exposure apparatus EX in the present embodiment is a scanning type exposure apparatus wherein the substrate P moves with respect to the immersion space LR. The movement of the substrate P can quickly remove adhered foreign matter from the front surface of the protective layer Tc.

In addition, even if part of the antireflection layer Ba peels off of the substrate P and mixes with the liquid LQ as foreign matter, the zeta potential of the protective layer Tc (the protective material) that forms the front surface (the surface layer) of the substrate P and the zeta potential of the antireflection layer Ba (the antireflection material) are of the same polarity, which makes it possible to prevent that part from adhering to the front surface (the protective layer Tc) of the substrate P.

In addition even if, for example, part of the protective layer Tc peels off of the substrate P and mixes in with the liquid LQ as foreign matter, it is possible to prevent the part, which has been peeled off from the substrate P, of the protective layer Tc (the protective material) from adhering to the front surface (the front surface of the protective layer Tc) of the substrate P because the zeta potential of the protective layer Tc (the protective material) that forms the front surface (the surface layer) of the substrate P has the same polarity as the zeta potential of the part of the protective layer Tc that mixes with the liquid LQ as foreign matter.

Thus, even if part of the film of the substrate P peels off of the substrate P and mixes with the liquid LQ as foreign matter, it is possible to prevent that foreign matter from adhering to the front surface of the substrate P, which makes it possible to prevent the generation of defects in the pattern formed in the substrate P.

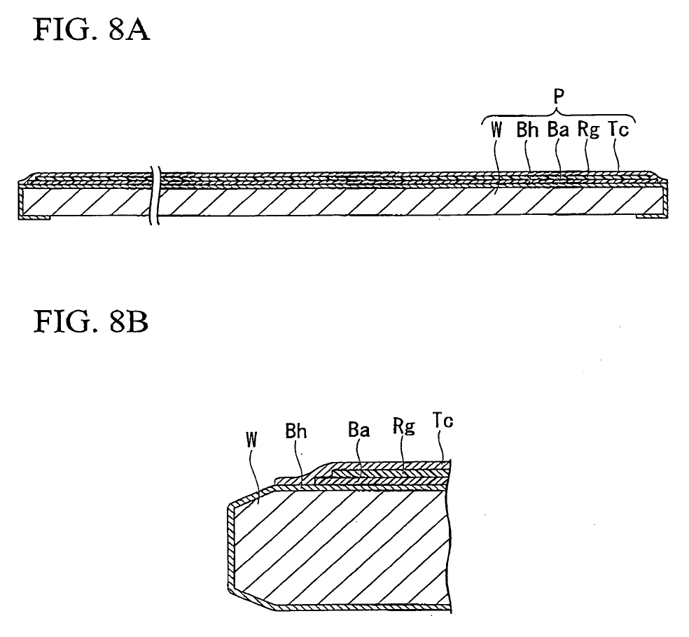

Furthermore, depending on the specifications of the substrate P, there are cases wherein the protective layer Tc covers the photosensitive layer Rg and the antireflection layer Ba, as shown in, for example, the schematic drawing of FIG. 8. In this case, the photosensitive layer Rg and the antireflection layer Ba do not contact the liquid LQ, which makes it possible to prevent part of the photosensitive layer Rg and the antireflection layer Ba from peeling off of the substrate P and mixing with the liquid LQ. In addition, with the substrate P as shown in FIG. 8, there is a possibility that part of the protective layer Tc will peel off of the substrate P and mix with the liquid LQ, but it is possible to prevent that part from adhering to the front surface (the front surface of the protective layer Tc) of the substrate P because the zeta potential of the protective layer Tc (the protective material) that forms the front surface (the surface layer) of the substrate P and the zeta potential of the part of the protective layer Tc that mixes with the liquid LQ are of the same polarity.

Alternatively, depending on the specifications of the substrate P, there is a case wherein the protective layer Tc covers only the photosensitive layer Rg. In this case, part of the antireflection layer Ba and the protection layer Tc may peel off from the substrate P, but it is possible to prevent the part of the antireflection layer Ba and the protection layer Tc from adhering to the substrate P in a similar manner.

Here, if the zeta potential of the protective layer Tc and the zeta potential of the foreign matter in the liquid LQ are of the same polarity, then the higher the absolute values of the zeta potential of the protective layer Tc and the zeta potential of the foreign matter are, the greater the repulsive force, which is caused by Coulomb force, is. Accordingly, it is preferable to use a material with a high absolute zeta potential value with respect to the liquid LQ for the material (the protective material) with which the protective layer Tc is formed. Thereby, it is possible to effectively prevent the foreign matter in the liquid LQ from adhering to the front surface (the front surface of the protective layer Tc) of the substrate P.

As discussed above, there are also cases wherein part of the protective layer Tc that peels off of the substrate P mixes with the liquid LQ as a foreign matter; in this case, it is possible to generate a large repulsive force, which is caused by Coulomb force, between the protective layer Tc and the foreign matter (part of the protective layer Tc) by selecting a material with a high absolute zeta potential value as the protective layer Tc that forms the front surface (the surface layer) of the substrate P. Thereby, it is possible to effectively prevent the part of the protective layer Tc that mixes with the liquid LQ from adhering to the front surface (the front surface of the protective layer Tc) of the substrate P.

Similarly, there are cases wherein part of the photosensitive layer Rg that peels off of the substrate P mixes with the liquid LQ as foreign matter; in this case, it is preferable to select a material with a high absolute zeta potential value if a material that has a zeta potential with a polarity that is the same as that of the material of the protective layer Tc is used for the photosensitive layer Rg.

Similarly, there are also cases wherein part of the antireflection layer Ba that peels off of the substrate P mixes with the liquid LQ as foreign matter; in this case, it is preferable to select a material with a high absolute zeta potential value if a material that has a zeta potential with a polarity the same as that of the material of the protective layer Tc is used for the antireflection layer Ba.

Thus, forming each of the layers, including the surface layer of the substrate P, with a material that has a desired zeta potential makes it possible to prevent foreign matter from adhering to the front surface of the substrate P and to prevent the generation of pattern defects caused by foreign matter.

In addition, there is also a possibility that, for example, part of the HMDS layer Bh will mix with the liquid LQ as foreign matter. In that case as well, selecting the materials used so that the zeta potential of the protective layer Tc (the protective material) that forms the front surface (the surface layer) of the substrate P and the zeta potential of the HMDS layer Bh are of the same polarity makes it possible to prevent part of the HMDS layer Bh, which acts as foreign matter, from adhering to the front surface (the front surface of the protective layer Tc) of the substrate P.

In addition, for the sake of simplicity, the above explained an exemplary case wherein each of the layers is formed on the silicon substrate; however, there are also cases wherein the front surface (the base) of the base material W is an oxide film layer of SiO₂. In addition, there are also cases wherein the front surface (the base) of the base material W is a front surface of at least one of: the SiO₂ oxide film layer that was formed up to the previous process; an insulating layer such as SiO₂ and SiNx; a metal conducting layer such as copper (Cu), tantalum (Ta), tungsten (W), and aluminum (Al); and a semiconductor layer such as amorphous silicon. In addition, there are also cases wherein the front surface (the base) of the base material W is a dielectric layer. The dielectric layer includes a so-called low-k material, which has a relative permittivity that is lower than that of air (approximately one), or a High-k material. In either case, there is a possibility that part of the base material W will mix with the liquid LQ as foreign matter. In that case, making the zeta potential of the protective layer Tc that forms the front surface (the surface layer) of the substrate P and the zeta potential of the base material W so that they are of the same polarity makes it possible to prevent the foreign matter that emanates from the base material W from adhering to the front surface (the front surface of the protective layer Tc) of the substrate P.

In addition, there is also a possibility that the foreign matter that emanates from the substrate P is foreign matter that adhered to the substrate P in, for example, a previous process. For example, there is a possibility the substrate P will be transported to the exposure apparatus EX in a state wherein the slurry used in the previous CMP process adheres to that substrate P. If the zeta potential of the foreign matter (the slurry) and the zeta potential of the surface layer of the substrate P are of the same polarity, then it is possible to prevent that foreign matter from adhering to the front surface of the substrate P.

In addition to the foreign matter that emanates from the substrate P, there is a possibility that particles suspended in the space wherein the exposure apparatus EX is disposed will mix with the liquid LQ as foreign matter. If the zeta potential of these particles and the zeta potential of the surface layer of the substrate P are of the same polarity, then it is possible to prevent those particles from adhering to the front surface of the substrate P.

As explained above, in the case wherein the substrate P is formed from multiple portions that are made of different materials, i.e., the protective layer Tc, which is made of the protective material, the photosensitive layer Rg, which is made of the photosensitive material, the antireflection layer Ba, which is made of the antireflection material, and the base material W, which includes the silicon substrate, the oxide film layer, a metal layer, and the insulating layer, making the zeta potentials of each portion with respect to the liquid LQ of the same polarity makes it possible to prevent the foreign matter that emanates from the substrate P from adhering to its front surface. Accordingly, it is possible to prevent exposure failures that are caused by the foreign matter adhering to the front surface of the substrate P, and thereby to expose the substrate P satisfactorily.

Furthermore, the present embodiment explained an exemplary case wherein the polarity of the zeta potential of the material that is used to form the protective layer Tc of the substrate P is negative, but a material with a positive polarity can also be used. In that case, it is possible to prevent the foreign matter from adhering to the protective layer Tc by selecting each of the materials so that the zeta potential of the material with which the protective layer Tc is formed and the zeta potentials of the materials with which, for example, the photosensitive layer Rg and the antireflection layer Ba are formed, which comprise the lower layers of the protective layer Tc, so that they are all of the same polarity.

### Second Embodiment

The following explains a second embodiment. In the explanation below, constituent parts that are identical or equivalent to those in the first embodiment discussed above are assigned identical symbols, and the explanations thereof are therefore abbreviated or omitted.

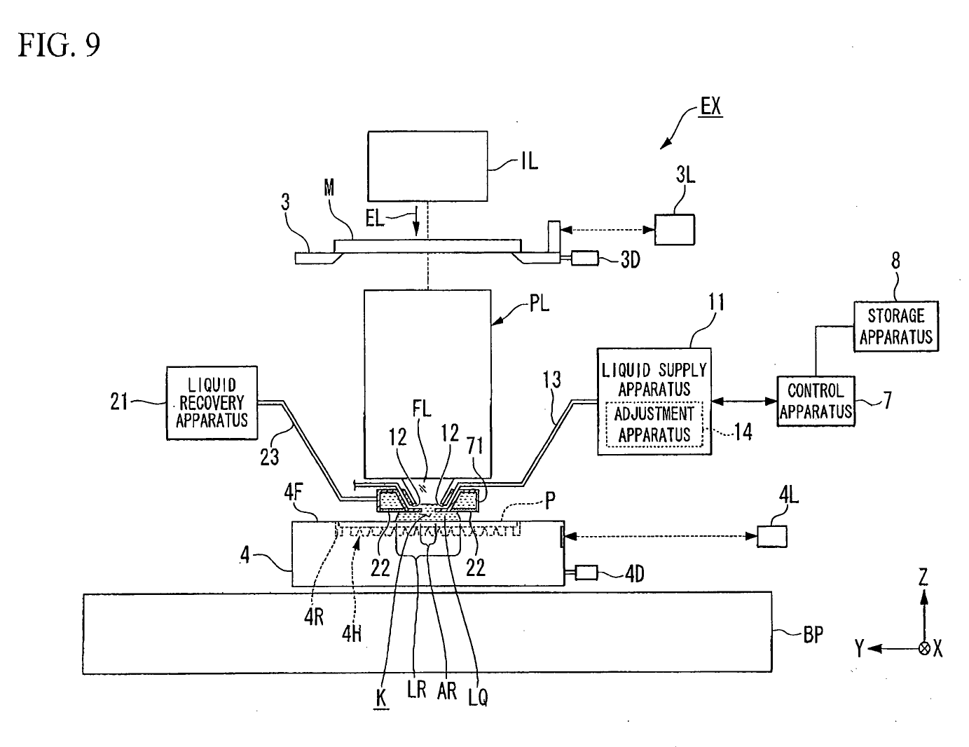

FIG. 9 shows an exposure apparatus EX according to the second embodiment. The exposure apparatus EX of the second embodiment comprises an adjustment apparatus 14 that adjusts the pH value of the liquid LQ in accordance with the material of the protective layer Tc that forms the front surface (the surface layer) of the substrate P. In the present embodiment, the adjustment apparatus 14 adjusts the pH value of the liquid LQ that is supplied from the liquid supply apparatus 11 to the supply port 12. The supply port 12 supplies the liquid LQ, for which the pH value is adjusted by the adjustment apparatus 14, to the optical path space K of the exposure light EL. Thereby, the pH value of the liquid LQ of the immersion space LR is adjusted.

In addition, the exposure apparatus EX is provided with a storage apparatus 8 that stores information related to the zeta potential of the protective material of the protective layer Tc of the substrate P. The storage apparatus 8 is connected to the control apparatus 7.

The zeta potential of the prescribed material is a value that is specific to that material and, as discussed above, varies in accordance with the pH value of the liquid that contacts that material.

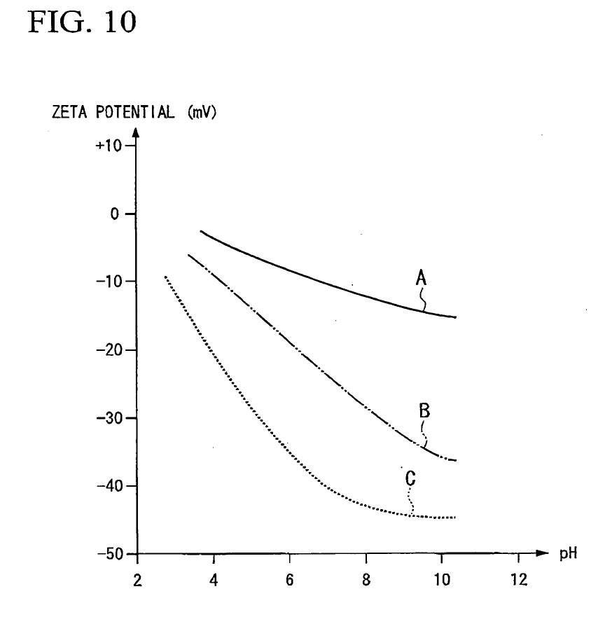

FIG. 10 is a view that shows one example of the relationship between the pH value of the liquid and the zeta potentials of materials A, B, C with respect to that liquid. The abscissa of the graph in FIG. 10 represents the pH value of the liquid and the ordinate represents the zeta potential of the material with respect to the liquid. As shown in FIG. 10, the zeta potential with respect to the liquid differs for each of the materials A, B, C. In addition, the zeta potential of each of the materials A, B, C varies in accordance with the pH value of the liquid. In the example shown in FIG. 10, the higher that the pH value of the liquid is, the higher that the absolute value of the zeta potential of each of the materials A, B, C is.

In the present embodiment, the exposure apparatus EX adjusts the pH value of the liquid LQ in accordance with the material (the protective material) of the protective layer Tc of the substrate P that contacts the liquid LQ of the immersion space LR. Specifically, the exposure apparatus EX adjusts the pH value of the liquid LQ that forms the immersion space LR using the adjustment apparatus 14 so that the repulsive force between the protective layer Tc of the substrate P and the foreign matter in the liquid LQ increases.

If the zeta potential of the material of the protective layer Tc of the substrate P and the zeta potential of the foreign matter are of the same polarity, then the higher that the absolute value of at least one of the zeta potential of the material of the protective layer Tc of the substrate P and the zeta potential of the foreign matter is, the higher that the repulsive force, which is caused by Coulomb force, is. In the present embodiment, the pH value of the liquid LQ that contacts the protective layer Tc of the substrate P is adjusted so that the absolute value of the zeta potential of the material of that protective layer Tc increases. Adjusting the pH value of the liquid LQ so that the absolute value of the zeta potential of the protective layer Tc increases makes it possible to increase the repulsive force, which is caused by Coulomb force, that acts between the protective layer Tc and the foreign matter.

For example, as represented by the material C shown in FIG. 10, if the zeta potential of the protective layer Tc with respect to the liquid LQ varies in accordance with the pH value of the liquid LQ, then the adjustment apparatus 14 increases the pH value of the liquid LQ (makes the liquid LQ alkaline) in order to increase the absolute value of the zeta potential of that protective layer Tc. Thereby, it is possible to increase the repulsive force, which is caused by Coulomb force, that acts between the protective layer Tc and the foreign matter.

In addition, adjusting the pH value of the liquid LQ also makes it possible to increase the absolute value of the zeta potential of the foreign matter of the liquid LQ.

In the present embodiment, the relationship between the pH value of the liquid LQ and the zeta potential of the protective layer Tc with respect to that liquid LQ is prestored in the storage apparatus 8. Furthermore, the relationship between the pH value of the liquid LQ and the zeta potential of the protective layer Tc can be prederived, for example, empirically or by simulation, and stored in the storage apparatus 8. The adjustment apparatus 14 adjusts the pH value of the liquid LQ based on the information stored in the storage apparatus 8 so that the absolute value of the zeta potential of the protective layer Tc increases. Here, the adjustment apparatus 14 adjusts the liquid LQ based on the storage information of the storage apparatus 8 so that the pH value of the liquid LQ increases (so that the liquid LQ becomes alkaline) in order to increase the absolute value of the zeta potential of the protective layer Tc.

In the present embodiment, the adjustment apparatus 14 adds a prescribed substance to the liquid LQ in order to adjust the pH value of the liquid LQ. For example, if the pH value of the liquid LQ is to be increased (if the liquid LQ is to be made alkaline), then the adjustment apparatus 14 adds ammonia to the liquid LQ (pure water). In addition, if the pH value of the liquid LQ is to be decreased (if the liquid LQ is to be made acidic), then the adjustment apparatus 14 adds carbonated gas (carbon dioxide) to the liquid LQ (pure water). Furthermore, the relationship between the quantity of the prescribed substance (carbonated gas or ammonia) that is added to the liquid LQ (pure water) and the pH value of the liquid LQ after the prescribed substance has been added is prederived, for example, empirically or by simulation, and stored in the storage apparatus 8. The adjustment apparatus 14 sets the quantity (the additive quantity) of the prescribed substance that is added to the liquid LQ (pure water) based on the storage information of the storage apparatus 8 so that the pH value of the liquid LQ reaches a desired value.

According to the present embodiment as explained above, it is possible to increase the repulsive force, which is caused by Coulomb force, that acts between the protective layer Tc and the foreign matter in the liquid LQ, and to prevent that foreign matter from adhering to the protective layer Tc, which forms the front surface of the substrate P.

Furthermore, the present embodiment explained a case wherein the higher that the pH value of the liquid LQ is, the higher that the absolute value of the zeta potential of the protective layer Tc with respect to the liquid LQ is; however, depending on the material with which the surface layer of the substrate P is formed, there is a possibility that the higher that the pH value of the liquid LQ is, the lower that the absolute value of the zeta potential of that material is. In such a case, the adjustment apparatus 14 adjusts the pH value of the liquid LQ to be supplied so that it decreases (so that the liquid LQ becomes acidic) in order to increase the absolute value of the zeta potential of the material.

Furthermore, the present embodiment explained an exemplary case wherein the zeta potential of the material that is used to form the surface layer of the substrate P is negative, but there is also a possibility that it is positive. Even in this case, the adjustment apparatus 14 adjusts the pH value of the liquid LQ so that the repulsive force between the surface layer of the substrate P and the foreign matter in the liquid LQ increases.

In addition, in a case wherein it is known that the polarity of the zeta potential of the foreign matter that mixes with the liquid LQ is different than that of the material with which the surface layer of the substrate P is formed, the pH value of the liquid LQ may be adjusted so that the attraction force between the foreign matter in the liquid LQ and the surface layer of the substrate P decreases.

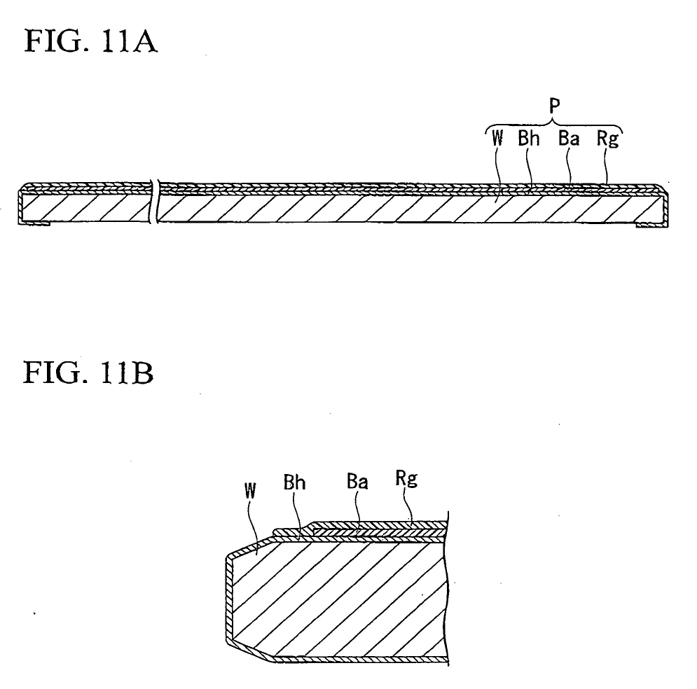

Furthermore, the first and second embodiments discussed above explained exemplary cases wherein the surface layer of the substrate P is the protective layer Tc, but the surface layer of the substrate P may be the photosensitive layer Rg, as shown in FIGS. 11A and 11B. In this case, in order to prevent the foreign matter from adhering to the surface layer (the photosensitive layer Rg) of the substrate P, the material of the photosensitive layer Rg and/or the material that is used to form the antireflection layer Ba below the photosensitive layer Rg are selected taking their zeta potentials into consideration. Alternatively, the adjustment apparatus 14 adjusts the pH value of the liquid LQ in accordance with the material of the photosensitive layer Rg in order to prevent the foreign matter from adhering to the surface layer (the photosensitive layer Rg) of the substrate P.

Namely, the substrate P may be one wherein only the photosensitive layer Rg is formed on the base material W, or it may be one wherein at least one of the protective layer Tc, the antireflection layer Ba, and the HMDS layer Bh is formed on and/or below the photosensitive layer Rg. In either case, the pH value of the liquid LQ should be adjusted by, for example, selecting the material that forms each layer talking its zeta potential with respect to the liquid LQ into consideration so as to prevent the foreign matter in the liquid LQ from adhering to the surface layer of the substrate P.

Furthermore, although the liquid LQ in each of the embodiments discussed above is water, it may be a liquid other than water. For example, it is also possible to use hydro-fluoro-ether (HFE), perfluorinated polyether (PFPE), Fomblin oil, cedar oil, or the like as the liquid LQ. In addition, a liquid that has a refractive index of approximately 1.6 to 1.8 may be used as the liquid LQ. In that case as well, it is possible to prevent foreign matter from adhering to the front surface of the substrate P by, for example, adjusting the pH value of the liquid LQ in accordance with the material of the surface layer of the substrate P, or selecting a material for each layer in accordance with its zeta potential with respect to the liquid LQ.

Furthermore, in each of the embodiments discussed above, the optical path space on the image plane (the emergent surface) side of the last optical element of the projection optical system is filled with the liquid, but it is also possible to fill the optical path space on the object plane (the incident surface) side of the last optical element with the liquid, as disclosed in PCT International Publication No. WO2004/019128.

Furthermore, the embodiments discussed above employ an exposure apparatus that locally fills the liquid LQ between the projection optical system PL and the substrate P, but can also employ a liquid immersion exposure apparatus that exposes the entire front surface of a substrate to be exposed in a state wherein the substrate is immersed in liquid, as disclosed in, for example, U.S. Pat. No. 5,825,043.

Furthermore, the substrate P in each of the embodiments discussed above is not limited to a semiconductor wafer for fabricating semiconductor devices, but can also be, for example, a glass substrate for display devices, a ceramic wafer for thin film magnetic heads, or a mask or the original plate of a reticle (synthetic quartz or a silicon wafer), a film member, and similar used by an exposure apparatus. Moreover, substrates are not limited to round shape, but may be rectangular or other shapes. A step-and-scan type scanning exposure apparatus (a scanning stepper) that scans and exposes the pattern of the mask M by synchronously moving the mask M and the substrate P or a step-and-repeat type projection exposure apparatus (a stepper) that performs full field exposure of the pattern of the mask M with the mask M and the substrate P in a stationary state and then sequentially steps the substrate P can be used as the exposure apparatus EX.

Furthermore, a stitching type full-field exposure apparatus, which performs a full-field exposure. On the substrate P, may be used as the exposure apparatus EX; in this case, a step-and-repeat type exposure is performed using a projection optical system to transfer a reduced image of a first pattern onto the substrate P in a state wherein the transferred first pattern and the substrate P are substantially stationary, after which the projection optical system is used to partially superpose a reduced image of a second pattern onto the first pattern in a state wherein the second pattern and the substrate P are substantially stationary. In addition, a step-and-stitch type exposure apparatus can be used as the stitching type exposure apparatus; in this case, at least two patterns are transferred onto the substrate P so that they partially overlap, after which the substrate P is sequentially stepped.

In addition, as disclosed in, for example, U.S. Pat. No. 6,611,316, the exposure apparatus EX can also be adapted to, for example, an exposure apparatus that combines the patterns of two masks on a substrate through a projection optical system and double exposes, substantially simultaneously, a single shot region on the substrate using a single scanning exposure. In addition, for example, a proximity type exposure apparatus or a mirror projection aligner can be used as the exposure apparatus EX.

In addition, the exposure apparatus EX can also be adapted to a twin stage type exposure apparatus that is provided with a plurality of substrate stages, as disclosed in, for example, U.S. Pat. Nos. 6,341,007 6,208,407, and 6,262,796.

Furthermore, as disclosed in, for example, U.S. Pat. No. 6,897,963, the exposure apparatus EX can also be adapted to an exposure apparatus that is provided with a substrate stage that holds the substrate, and a measurement stage that does not hold a substrate and whereon a fiducial member (wherein a fiducial mark is formed) and/or various photoelectric sensors are mounted. In addition, the exposure apparatus EX can be adapted to an exposure apparatus that comprises a plurality of substrate stages and measurement stages.

The type of exposure apparatus EX is not limited to a semiconductor device fabrication exposure apparatus that exposes the substrate P with the pattern of a semiconductor device, but can also be widely adapted to exposure apparatuses that are used for fabricating, for example, liquid crystal devices or displays, and to exposure apparatuses that are used for fabricating thin film magnetic heads, image capturing devices (CCDs), micromachines, MEMS, DNA chips, or reticles and masks.

Furthermore, in each of the embodiments above, the positional information of the mask stage 3 and the substrate stage 4 is measured using an interferometer system that comprises the laser interferometers, but the present invention is not limited thereto and, for example, an encoder system may be used that detects a scale (diffraction grating) that is provided to each of the stages. In this case, the system is preferably configured as a hybrid system that is provided with both an interferometer system and an encoder system, and it is preferable to use the measurement results of the interferometer system to calibrate the measurement results of the encoder system. In addition, the position of the stages may be controlled by switching between the interferometer system and the encoder system, or by using both.

In addition, in each of the embodiments discussed above, an ArF excimer laser may be used as a light source apparatus that generates. ArF excimer laser light, which serves as the exposure light EL; however, as disclosed in, for example, U.S. Pat. No. 7,023,610, a harmonic generation apparatus may be used that outputs pulsed light with a wavelength of 193 nm and that comprises: an optical amplifier part, which has a solid state laser light source (such as a DFB semiconductor laser or a fiber laser), a fiber amplifier, and the like; and a wavelength converting part. Furthermore, in the abovementioned embodiments, both the illumination area and the projection area are rectangular, but they may be some other shape, e.g., arcuate.

Furthermore, in the embodiments discussed above, a light transmitting type mask is used wherein a prescribed shielding pattern (or a phase pattern or a dimming pattern) is formed on a light transmitting substrate; however, instead of such a mask, a variable forming mask (also called an electronic mask, an active mask, or an image generator), wherein a transmittance pattern, a reflected pattern, or a light emitting pattern is formed based on electronic data of the pattern to be exposed, may be used as disclosed in, for example, U.S. Pat. No. 6,778,257. The variable forming mask comprises a DMD (digital micromirror device), which is one kind of non-emissive type image display device (also called a Spatial Light Modulator (SLM)). The exposure apparatus using a DMD is disclosed for example in U.S. Pat. No. 6,778,257. In addition, the variable forming mask is not limited to a DMD, and a non-emissive type image display device, which is explained below, may be used instead. Here, the non-emissive type image display device is a device that spatially modulates the amplitude (the intensity), the phase, or the polarization state of the light that travels in a prescribed direction; furthermore, examples of a transmissive type spatial light modulator include a transmissive type liquid crystal display (LCD) device as well as an electrochromic display (ECD). In addition, examples of a reflecting type spatial light modulator include a DMD, which was discussed above, as well as a reflecting mirror array, a reflecting type liquid crystal display device, an electrophoretic display (EPD), electronic paper (or electronic ink), and a grating light valve.

In addition, instead of a variable forming mask that is provided with a non-emissive type image display device, a pattern forming apparatus that comprises a self luminous type image display device may be provided. In this case, the illumination system is not needed. Here, examples of a self luminous type image display device include a CRT (cathode ray tube), an inorganic electroluminescence display, an organic electroluminescence display (OLED: organic light emitting diode), an LED display, an LD display, a field emission display (FED), and a plasma display (PDP: plasma display panel). In addition, a solid state light source chip that has a plurality of light emitting points, a solid state light source chip array wherein a plurality of chips are arrayed, a device in which a plurality of light emitting points are created on a single substrate, or the like may be used as the self luminous type image display device that is provided with the pattern forming apparatus, and the pattern may be formed by electrically controlling the solid state light source chip(s). Furthermore, it does not matter whether the solid state light source device is inorganic or organic.

Each of the embodiments discussed above explained an exemplary case of an exposure apparatus that is provided with the projection optical system PL, but these can be adapted to an exposure apparatus and an exposing method that do not use the projection optical system PL. Thus, even if the projection optical system PL is not used, the exposure light is radiated onto the substrate through optical members, e.g., lenses, and an immersion space is formed in a prescribed space between the substrate and those optical members.

In addition, by forming interference fringes on the substrate P as disclosed in, for example, PCT International Publication WO2001/035168, the exposure apparatus EX can also be adapted to an exposure apparatus (a lithographic system) that exposes the substrate P with a line-and-space pattern.

The exposure apparatus EX of the embodiments is manufactured by assembling various subsystems that include each constituent element so that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus EX from the various subsystems includes, for example, the mechanical interconnection of the various subsystems, the wiring and connection of electrical circuits, and the piping and connection of the atmospheric pressure circuit. Naturally, prior to performing the process of assembling the exposure apparatus EX from these various subsystems, there are also the processes of assembling each individual subsystem. When the process of assembling the exposure apparatus EX from the various subsystems is complete, a comprehensive adjustment is performed to ensure the various accuracies of the exposure apparatus EX as a whole. Furthermore, it is preferable to manufacture the exposure apparatus EX in a clean room wherein, for example, the temperature and the cleanliness level are controlled.

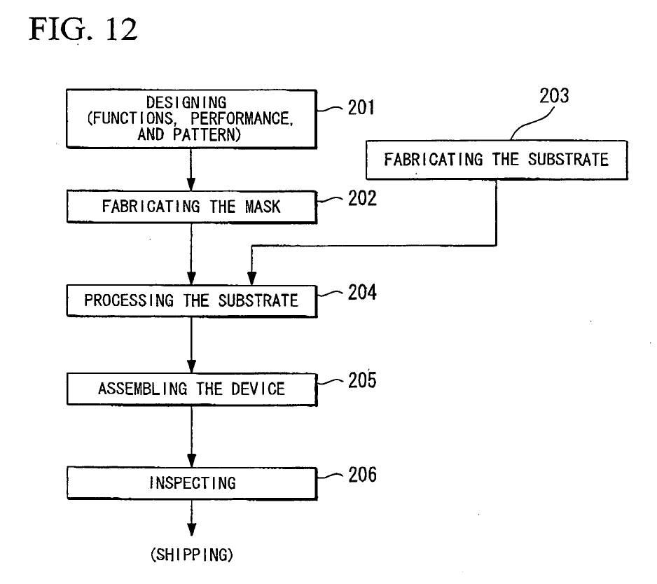

As shown in FIG. 12, a micro-device, such as a semiconductor device, is manufactured by: a step 201 that designs the functions and performance of the micro-device; a step 202 that fabricates a mask (a reticle) based on this designing step; a step 203 that fabricates a substrate, which is the base material of the device; a substrate processing step 204 that includes a substrate process (an exposure process) wherein, in accordance with the embodiments discussed above, the substrate is exposed with a pattern of the mask and the exposed substrate is then developed; a device assembling step 205 (comprising fabrication processes such as a dicing process, a bonding process, and a packaging process); an inspecting step 206; and the like.

Furthermore, the above explained the embodiments of the present invention, but the present invention can be used by appropriately combining all of the constituent elements, and can also be used in cases wherein some of the constituent elements are not used.

As far as is permitted, each disclosure of every Publication and U.S. patent related to the exposure apparatus recited in each of the abovementioned embodiments, modified examples, and the like is hereby incorporated by reference.

1. An exposing method, comprising:
exposing a substrate through a liquid; and
adjusting a pH value of the liquid in accordance with a material of a surface layer of the substrate that contacts the liquid.

2. An exposing method according the claim 1, wherein
the pH value is adjusted so that a repulsive force between the surface layer of the substrate and foreign matter in the liquid increases.

3. An exposing method according to claim 2, wherein
the pH value of the liquid is adjusted so that at least one of an absolute value of a zeta potential of the material of the surface layer of the substrate and an absolute value of a zeta potential of the foreign matter increases.

4. An exposing method according to claim 1, wherein
the liquid comprises water; and
the adjustment value of the PH value comprises adding a prescribed substance to the liquid.

5. An exposing method according to claim 4, wherein
the prescribed substance comprises at least one of carbonated gas and ammonia.

6. An exposing method according to claim 1, wherein
the surface layer of the substrate comprises a photosensitive layer.

7. An exposing method according to claim 6, wherein
the surface layer of the substrate comprises a protective layer that is formed on the photosensitive layer.

8. An exposing method that exposes a substrate through a liquid, wherein
the substrate includes a first portion that comprises a first material and a second portion that comprises a second material that is different from the first material; and
a zeta potential of the first material and a zeta potential of the second material with respect to the liquid are of the same polarity.

9. An exposing method according to claim 8, wherein
the first portion and the second portion each have an exposed part that is capable of contacting the liquid.

10. An exposing method according to claim 8, wherein
the first portion comprises a surface layer that contacts the liquid.

11. An exposing method according to claim 10, wherein
the second portion comprises a lower layer, at least part of which is formed below the surface layer.

12. An exposing method according to claim 11, wherein
the second portion comprises a base material whereon the surface layer and the lower layer are formed.

13. An exposing method according to claim 8, wherein
the first portion comprises a photosensitive layer.

14. An exposing method according to claim 8, wherein
the first portion comprises a protective layer that protects the second portion.

15. An exposing method according to claim 14, wherein
the second portion comprises at least one of a photosensitive layer and an antireflection layer, which are formed below the protective layer.

16. An exposing method according to claim 8, wherein
the second portion comprises at least one of a silicon substrate, an oxide film layer, a metal layer, and an insulating layer.

17. A device fabricating method, comprising:
exposing a substrate using an exposing method according to claim 1; and
developing the exposed substrate.

18. An exposure apparatus that exposes a substrate through a liquid, comprising:
an adjustment apparatus that adjusts a pH value of the liquid in accordance with a material of a surface layer of the substrate that contacts the liquid.

19. An exposure apparatus according to claim 18, further comprising:
a storage apparatus that stores information related to a zeta potential of the material of the surface layer of the substrate;
wherein,
the adjustment apparatus adjusts the pH value of the liquid based on the storage information of the storage apparatus so that an absolute value of a zeta potential of the material of the surface layer of the substrate increases.

20. A device fabricating method, comprising:
exposing a substrate using an exposure apparatus according to claim 18; and
developing the exposed substrate.

21. A substrate for immersion exposure that is irradiated with exposure light through a liquid, the substrate comprising:
a first portion that comprises a first material; and
a second portion that comprises a second material that is different from the first material;
wherein,
a zeta potential of the first material and a zeta potential of the second material with respect to the liquid are of the same polarity.
